(19) United States
(12) Patent Application Publication
(10) Pub. No.: US 2024/0347565 A1
(43) Pub. Date: Oct. 17, 2024

(54) ELECTRONIC COMPONENT AND EQUIPMENT

(71) Applicant: CANON KABUSHIKI KAISHA, Tokyo (JP)

(72) Inventors: YU KATASE, Kanagawa (JP); SUSUMU MATSUMOTO, Kanagawa (JP); SATORU HAMASAKI, Kanagawa (JP); TAIKI SHITAMICHI, Kanagawa (JP)

(21) Appl. No.: 18/625,541

(22) Filed: Apr. 3, 2024

(30) Foreign Application Priority Data
Apr. 13, 2023 (JP) 2023-065900

(51) Int. Cl. H01L 27/146; G02F 1/1333; H01L 23/00

(52) U.S. Cl. CPC H01L 27/14618; G02F 1/133331; H01L 24/45; H01L 24/48; H01L 24/49; H01L 2224/45124; H01L 2224/45139; H01L 2224/45144; H01L 2224/45147; H01L 2224/48091; H01L 2224/48225; H01L 2224/49176

(57) ABSTRACT

An electronic component that includes a base body with an electronic device placed on a placement surface, and a lid including a surface facing the electronic device and fixed to the base body, is provided. On the surface of the lid, a thin film in contact with the surface is arranged. In an orthogonal projection with respect to the placement surface, the thin film comprises a first portion including a region which overlaps the electronic device, and a second portion arranged so as to surround the first portion and including an outer edge of the thin film, and the second portion applies, to a portion of the lid in contact with the second portion, a force in a direction from a center of the thin film toward the outer edge.

### BACKGROUND OF THE INVENTION

### Field of the Invention

The present invention relates to an electronic component and equipment.

### Description of the Related Art

In an electronic component accommodating an electronic device, a great stress may be applied to the electronic component due to a change in use environment such as temperature. Japanese Patent Laid-Open No. 2019-129276 describes that damage of the electronic component is prevented by providing a continuous protrusion in the circumferential direction of a frame to which a lid portion is adhered.

Along with a reduction in size of the electronic device or the electronic component itself, it is demanded to decrease the thickness of the lid which covers the base body where the electronic device is placed. If the thickness of the lid is decreased, when a stress is applied to the lid due to a change in use environment of the electronic component or the like, the lid is easily damaged by breakage or the like.

Some embodiments of the present invention provide a technique advantageous in suppressing damage of a lid.

### SUMMARY OF THE INVENTION

According to some embodiments, an electronic component that comprises a base body with an electronic device placed on a placement surface, and a lid including a surface facing the electronic device and fixed to the base body, wherein on the surface of the lid, a thin film in contact with the surface is arranged, in an orthogonal projection with respect to the placement surface, the thin film comprises a first portion including a region which overlaps the electronic device, and a second portion arranged so as to surround the first portion and including an outer edge of the thin film, and the second portion applies, to a portion of the lid in contact with the second portion, a force in a direction from a center of the thin film toward the outer edge, is provided.

According to some other embodiments, an electronic component that comprises a base body with an electronic device placed on a placement surface, and a lid including a surface facing the electronic device and fixed to the base body, wherein on the surface of the lid, a thin film in contact with the surface is arranged, in an orthogonal projection with respect to the placement surface, the thin film comprises a first portion including a region which overlaps the electronic device, and a second portion arranged so as to surround the first portion and including an outer edge of the thin film, the first portion applies, to a portion of the lid in contact with the first portion, a force in a direction from the outer edge toward a center of the thin film, and the second portion applies, to a portion of the lid in contact with the second portion, a force in the direction which is smaller than the force of the first portion, is provided.

Further features of the present invention will become apparent from the following description of exemplary embodiments (with reference to the attached drawings).

### BRIEF DESCRIPTION OF THE DRAWINGS

FIG. 1A is a plan view showing an example of the arrangement of an electronic component according to an embodiment;

FIG. 1B is a sectional view showing the example of the arrangement of the electronic component according to the embodiment;

FIG. 2 shows a plan view and a sectional view of an example of the arrangement of a lid of the electronic component shown in FIGS. 1A and 1B;

FIG. 3 shows a plan view and a sectional view of the relationship between the lid shown in FIG. 2 and a jig for forming a thin film;

FIG. 4 is an enlarged view of the lid shown in FIG. 2;

FIGS. 5A to 5C are sectional views each showing an example of the arrangement of a thin film formed on the lid shown in FIG. 2;

FIGS. 6A to 6C are sectional views each showing an example of the arrangement of the thin film formed on the lid shown in FIG. 2;

FIGS. 7A and 7B are a plan view and a sectional view, respectively, showing a modification of the electronic component shown in FIGS. 1A and 1B;

FIG. 8 shows a plan view and a sectional view of an example of the arrangement of the lid of the electronic component shown in FIGS. 7A and 7B;

FIGS. 9A and 9B are a plan view and a sectional view, respectively, showing a modification of the electronic component shown in FIGS. 7A and 7B;

FIG. 10 shows a plan view and a sectional view of an example of the arrangement of the lid of the electronic component shown in FIGS. 9A and 9B;

FIG. 11 is a sectional view showing an example of the arrangement of a thin film formed on the lid shown in FIG. 2;

FIGS. 12A and 12B are enlarged views of the lid shown in FIG. 11;

FIG. 13 shows a plan view and a sectional view of the relationship between the lid shown in FIG. 11 and a jig for forming a thin film; and

FIG. 14 is a view showing an example of the arrangement of equipment incorporating an electronic component according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

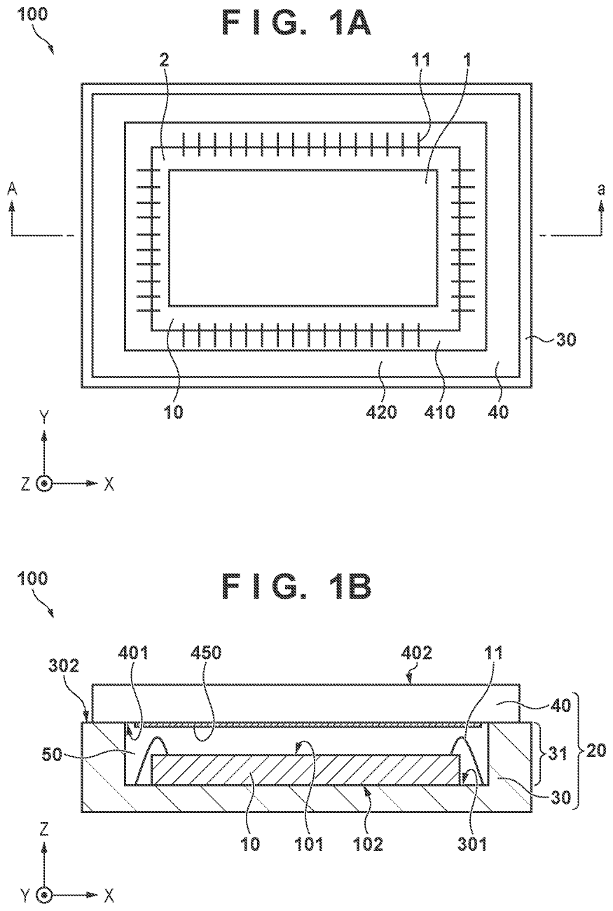

With reference to FIGS. 1A to 13B, an electronic component according to an embodiment of the present disclosure will be described. FIGS. 1A and 1B are schematic views of an electronic component 100 according to this embodiment. FIG. 1A is a plan view showing an example of the arrangement of the electronic component 100. FIG. 1B is a sectional view taken along a line A—a shown in FIG. 1A. In each drawing, X, Y, and Z directions are shown. Hereinafter, the X and Y directions will sometimes be referred to as the plane direction of the electronic component 100, and the Z direction will sometimes be referred to as the thickness direction of the electronic component 100.

The electronic component 100 includes an electronic device 10, a base body 30 with the electronic device 10 placed on a placement surface 301, and a lid 40 including a surface 401 facing the electronic device 10 and fixed to the base body 30. A combination of the base body 30 and the lid 40 can be called a package 20.

The base body 30 can function as a mounting body that mechanically fixes the electronic component 100 and can also electrically connect it. The lid 40 can function as an optical member. A surface 102 of the electronic device 10 is fixed to the placement surface 301 of the base body 30 by using a joint member such as an adhesive. The lid 40 is fixed to an upper surface 302 of a frame portion 31 of the base body 30, which is formed into a frame shape, by using a joint member such as an adhesive. It can also be said that the base body 30 includes the frame portion 31 with the lid 40 fixed thereto. When the lid 40 is fixed to the base body 30, the package 20 has an internal space 50 surrounded by the base body 30 and the lid 40. Accordingly, it can also be said that the electronic device 10 is arranged in the internal space 50 of the package 20.

The X direction and the Y direction can be directions parallel to a surface 101 of the electronic device 10 facing the lid 40, and the surface 102 which is the surface on the opposite side of the surface 101 and fixed to the base body 30. Further, the X direction and the Y direction can be directions parallel to the surface 401 of the lid 40 facing the electronic device, and a surface 402 on the opposite side of the surface 401. The Z direction is a direction intersecting the surface 401 and the surface 402. The Z direction may be a direction orthogonal to the surface 401 and the surface 402. That is, the Z direction is a direction intersecting the X direction and the Y direction, and may be a direction orthogonal to the X direction and the Y direction.

Each of the electronic device 10 and the package 20 can have a polygonal shape in the X direction and the Y direction. In other words, in an orthogonal projection with respect to the placement surface 301 of the base body 30 forming the package 20, each of the electronic device 10 and the package 20 may have a polygonal shape. Further, each of the base body 30 and the lid 40 forming the package 20 may have a polygonal shape in the orthogonal projection with respect to the placement surface 301 of the base body 30. Typically, in the orthogonal projection with respect to the placement surface 301, each of the electronic device 10, the base body 30, and the lid 40 can have a rectangular shape as shown in FIG. 1A. Here, the rectangular shape can include not only a quadrangle such as a rectangle or a square but also a shape formed by chamfering each vertex of a quadrangle.

The Z-direction dimension of each of the electronic device 10 and the package 20 is typically smaller than the X-direction dimension and the Y-direction dimension as shown in FIGS. 1A and 1B. Accordingly, each of the electronic device 10 and the package 20 can have an approximately flat plate shape.

The kind of the electronic device 10 is not particularly limited, but can typically be an optical device. In this embodiment, the electronic device 10 includes a primary region 1 and a secondary region 2. The primary region 1 is located at the center of the electronic device 10, and the secondary region 2 is located around the primary region 1. If the electronic device 10 is an image capturing device such as a CCD image sensor or a CMOS image sensor, the primary region 1 serves as an image capturing region. If the electronic device 10 is a display device such as a liquid crystal display or an electroluminescence (EL) display, the primary region 1 serves as a display region. If the electronic device is the image capturing device or the display device, a plurality of pixels for performing image capturing or display can be arranged in the primary region 1.

If the electronic device 10 is the image capturing device, the surface 101 of the electronic device 10 facing the lid 40 serves as a light incident surface. If the electronic device 10 is the display device, the surface 101 of the electronic device 10 facing the lid 40 serves as a light exit surface. Each of the light incident surface and the light exit surface can be formed by an outermost layer of a multilayered film provided on a semiconductor substrate or the like forming the electronic device 10. The multilayered film can include a layer having an optical function such as a color filter layer, a microlens layer, an antireflection layer, or a light-shielding layer, a layer having a mechanical function such as a planarizing layer, a layer having a chemical function such as a passivation layer, and the like.

In the secondary region 2 of the electronic device 10, a driving circuit for driving an element such as the pixel arranged in the primary region 1 can be provided. In the secondary region 2 of the electronic device 10, a signal processing circuit for processing a signal output form the primary region 1 or a signal supplied to the primary region 1, and the like can also be provided. If the electronic device 10 is a semiconductor device, it is easy to monolithically form the driving circuit, the signal processing circuit, or the like. Alternatively, for example, the electronic device 10 may be formed by stacking two or more electronic devices. In this case, the electronic device 10 may be formed by stacking an electronic device serving as the secondary region 2 under (on the placement surface 301 side of the base body 30) an electronic device serving the primary region 1.

As shown in FIG. 1B, the base body 30 of the package 20 may have a concave shape. That is, the base body 30 may have a structure in which the placement surface 301, where the electronic device 10 is placed, is recessed from the upper surface 302 of the frame portion 31 formed in a frame shape. The base body 30 can be formed by, for example, die molding, cutting processing, stacking plate materials, or the like. The base body 30 may be a conductor such as a metal plate, or may be an insulator such as a resin. Alternatively, for example, the base body 30 may have an arrangement in which a surface of a base portion made of a conductor is covered with an insulator.

The base body 30 may be, for example, a flexible substrate such as a polyimide substrate. Alternatively, for example, the base body 30 may be a rigid substrate such as a glass epoxy substrate, a composite substrate, a glass composite substrate, a Bakelite substrate, or a ceramic substrate. In some cases, a ceramic substrate and a glass epoxy substrate are suitable for the substrate 30.

If the base body 30 is a ceramic substrate, a ceramic laminate may be used as the base body 30. As the material of the ceramic substrate, silicon carbide, aluminum nitride, sapphire, alumina, silicon nitride, cermet, yttria, mullite, forsterite, cordierite, zirconia, steatite, or the like can be used.

If the base body 30 is a glass epoxy substrate, in order to form the concave shape as shown in FIG. 1B, an arrangement may be used in which a flat plate-like glass epoxy substrate is provided as the base body 30 and a frame body (for example, the frame portion 31) is provided in the outer peripheral portion of the glass epoxy substrate. For the frame body, ceramic, a metal, a resin material, or the like may be used. As a metal material used for the frame body, aluminum, an aluminum alloy, copper, a copper alloy, an iron alloy, or the like may be used. In some cases, an iron alloy containing chromium, nickel, or cobalt, which is represented by stainless steel, is suitable as the metal material of the frame body. As the metal material of the frame body, for example, SUS430 as ferritic stainless steel, SUS304 as austenite stainless steel, 42 Alloy, or kovar can be used. As a resin material used for the frame body, an epoxy resin, an acrylic resin, a silicone resin, a vinyl resin, or the like may be used. Examples of the resin material include a dry solidification-type material by solvent evaporation, a chemical reaction-type material that is cured by polymerization of molecules by light or heat, and a hot melt-type material that is cured by solidification of a melted material. When the resin material is used to form the frame body, typically, a photo-curable resin that is cured by ultraviolet light or visible light or a thermosetting resin that is cured by heat can be used.

The electronic device 10 forming the electronic component 100 may be electrically connected to an internal terminal provided in the base body 30 by a wire 11 using, for example, gold, silver, copper, aluminum, or an alloy thereof. With this, the electronic device 10 is electrically connected to an external circuit arranged outside the electronic component 100 via the wire 11, the internal terminal, and an external terminal provided in the base body 30. For the external terminal, appropriate configuration and component are used, such as a Land Grid Array (LGA), a Pin Grid Array (PGA), a Ball Grid Array (BGA), a Leadless Chip Carrier (LCC), a lead frame, a connector, or the like. For example, reflow soldering using a solder paste can implement connection between the external terminal and the external circuit. In this way, the electronic component 100 is secondarily implemented to form an electronic module. Electronic equipment can be formed by incorporating the electronic module in a housing.

The lid 40 facing the electronic device includes the surface 401 facing the electronic device 10, the surface 402 on the opposite side of the surface 401, and a side surface 403 connecting the surface 401 and the surface 402. The portion between the surface 401 and the side surface may be chamfered. Similarly, the portion between the surface 402 and the side surface may be chamfered. If the electronic device 10 is the image capturing device or the display device as described above, a transparent material that transmits light is used for the lid 40. For example, as the material of the lid 40, glass, quartz, or the like may be used.

Here, a region of the lid 40 located on the inner edge side of the region adhered to the base body 30, more specifically, a region of the lid 40 that overlaps the internal space 50 in the orthogonal projection with respect to the placement surface 301, will be referred to as a region 410 hereinafter. Further, a region of the lid 40 including the outer edge of the lid 40 and surrounding the region 410 in the orthogonal projection with respect to the placement surface 301 will be referred to as a region 420. It can also be said that the region 420 is a region that overlaps the frame portion 31 of the base body 30 in the orthogonal projection with respect to the placement surface 301.

On the surface 401 of the lid 40, a thin film 450 in contact with the surface 401 is arranged for the purpose of antireflection coating, infrared cutting coating, or the like. As shown in FIG. 1B, the thin film 450 is arranged in the region 410 of the surface 401 of the lid 40. As will be described later, the thin film 450 may be arranged on the surface 401 of the lid 40 from the region 410 to the region 420. The thin film 450 can be formed using a vacuum deposition method, a sputtering method, or the like. The thin film 450 may be formed by a single material layer. Alternatively, in order to improve the antireflection function, infrared cutting function, and the like, the thin film 450 may have a stacked structure in which at least two kinds of material layers using materials different from each other are stacked.

The thin film 450 can be formed by, for example, alternately stacking a material layer using a low refractive index material and a material layer using a high refractive index material. The thin film 450 can be formed such that desired spectral characteristics such as reflectance are obtained by the interference action between the light reflected on the surface of the thin film 450 and the light components reflected on the interfaces of the respective materials forming the thin film 450 and the interface of the lid 40. Examples of the low refractive index material include SiO₂, MgF₂, CaF₂, LaF₃, Al₂O₃, and the like. In some cases, Al₂O₃ can be used as an intermediate refractive index material positioned between the low refractive index material and the high refractive index material. Examples of the high refractive index material include TiO₂, Ti₃O₅, ZnS, ZrO₂, Ta₂O₅, La₂Ti₂O₆, Nb₂O₅, and the like. The thickness of one material layer of the thin film 450 can be about a few nm to several hundred nm. In the following drawings including FIG. 1B, the thin film 450 is shown thicker than its actual thickness so that it can be visually recognized.

When the thin film 450 is formed on the surface 401 of the lid 40, a stress is generated between the surface 401 of the lid 40 and the thin film 450. There are two kinds of internal stresses applied to the thin film 450: compressive stress and tensile stress. Whether the internal stress of the thin film 450 is compressive stress or tensile stress depends on the stress specific to the material of the thin film 450, the conditions for forming the thin film 450, the difference in linear expansion coefficient between the thin film 450 and the lid 40, and the like. Here, the compressive stress as the internal stress of the thin film 450 is a force for contracting the thin film 450. In this case, the thin film 450 applied, to the portion of the lid 40 with the thin film 450 formed, a force in a direction from the outer edge of the thin film 450 toward the center of the thin film 450. With respect to this force, a reaction force for expanding the lid 40 acts on the portion of the lid 40 with the thin film 450 formed. On the other hand, the tensile stress as the internal stress of the thin film 450 is a force for expanding the thin film 450. In this case, the thin film 450 applies, to the portion of the lid 40 with the thin film 450 formed, a force in a direction from the center of the thin film 450 toward the outer edge of the thin film 450. With respect to this force, a reaction force for contracting the lid 40 acts on the portion of the lid 40 with the thin film 450 formed. The smaller the thickness of the lid 40 or the lower the strength of the material of the lid 40, the larger the influence of the internal stress of the thin film 450.

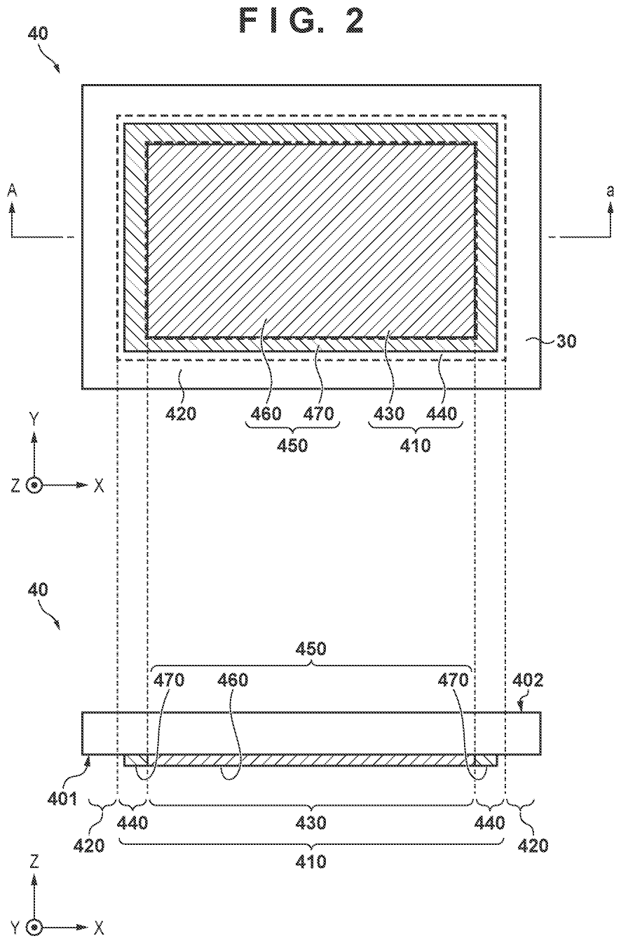

FIG. 2 is a schematic view showing an example of the arrangement of the lid 40. A plan view of the lid 40 is shown on the upper side, and a sectional view of the lid 40 is shown on the lower side. The sectional view shows a section of the lid 40 taken along a line A-a in the plan view. With reference to FIG. 2, the lid 40 will be described in more detail. In the orthogonal projection with respect to the placement surface 301, the region 410 of the lid 40 described above includes a region 430 which overlaps the electronic device 10, and a region 440 surrounding the region 430. It can also be said that the region 410 is formed by the region 430 and the region 440.

In the orthogonal projection with respect to the placement surface 301, the thin film 450 includes a portion 460 including a region which overlaps the electronic device 10, and a portion 470 arranged so as to surround the portion 460 and including the outer edge of the thin film 450. It can also be said that the thin film 450 is formed by the portion 460 and the portion 470. The portion 460 of the thin film 450 including the region which overlaps the electronic device 10 needs to have specifications that implement the antireflection performance, infrared cutting performance, and the like required for the electronic component 100. In the arrangement shown in FIG. 2, the portion 460 of the thin film 450 is arranged so as to overlap the region 430 of the lid 40, and the portion 470 of the thin film 450 is arranged so as to overlap the region 440 of the lid 40. However, the present invention is not limited to this, and the portion 460 of the thin film 450 may be arranged so as to overlap the region 440 of the lid 40. Alternatively, for example, the portion 470 of the thin film 450 may be arranged so as to overlap the region 430 of the lid 40 to the extent not to impair the specifications required for the electronic component 100 such as antireflection and infrared cutting performances.

Alternatively, the portion 470 forming the outer edge of the thin film 450 may be arranged in the region 420 of the lid 40. That is, in the orthogonal projection with respect to the placement surface 301, the outer edge of the thin film 450 may be arranged so as to overlap the frame portion 31 of the base body 30. On the other hand, in a case in which the adhesive used as the joint member for joining the base body 30 and the lid 40 is an ultraviolet curing adhesive or the like, the portion 470 of the thin film 450 can be a factor that hinders curing of the adhesive. Therefore, the thin film 450 may not be formed in the region 420 of the lid 40. That is, in the orthogonal projection with respect to the placement surface 301, the outer edge of the thin film 450 may be arranged on the inner side of the frame portion 31 of the base body 30. In this case, further, in consideration of a formation shift of the portion 470 of the thin film 450 and a shift of the fixing position between the base body 30 and the lid 40, the thin film 450 may not be formed in the entire region 440 of the lid 40, that is, may not be formed in the outer peripheral portion of the region 440. The region of the region 440 of the lid 40 where the thin film 450 is not arranged can be designed, as appropriate, from the alignment margin upon forming the portion 470 of the thin film 450 and the alignment margin upon fixing the base body 30 and the lid 40.

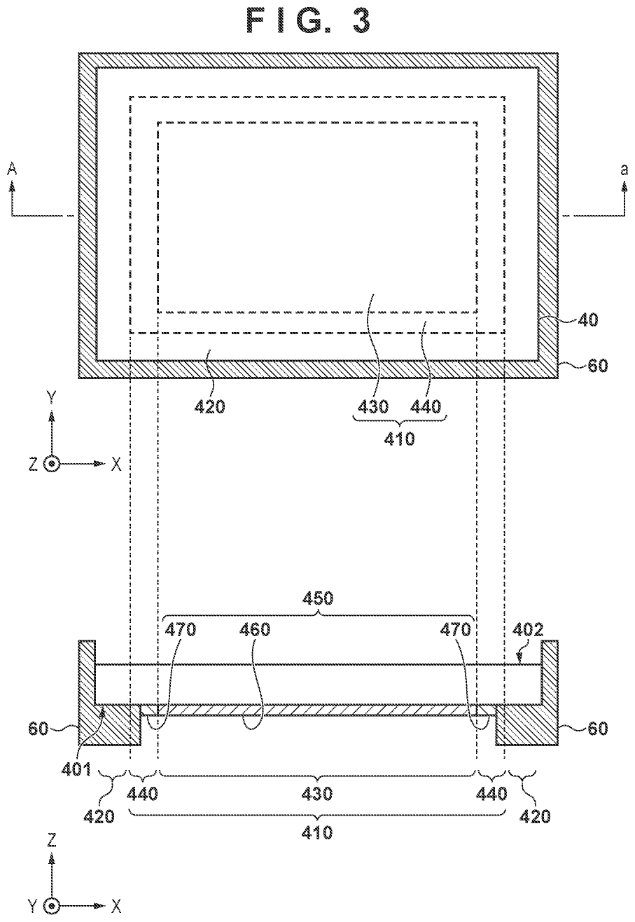

FIG. 3 is a schematic view showing the relationship between the lid 40 and a jig 60 upon forming the thin film 450 on the lid 40. A plan view in a state in which the lid 40 is set in the jig 60 is shown on the upper side of FIG. 3, and a sectional view is shown on the lower side. The sectional view shows a section taken along a line A-a in the plan view. The jig 60 may be, for example, made of a metal in consideration of durability, shape stability, deposition environment, and the like. The jig 60 may have, for example, a shape that holds the outer shape of the lid 40 in the plane direction (X-Y direction), and the outer peripheral portion of the region 440 and the region 420 on the surface 401 side of the lid 40. In other words, the region 430 and the inner peripheral portion of the region 440 on the surface 401 side of the lid 40 are not held by the jig 60, and the jig 60 has an opening in a region corresponding to the region 430 and the inner peripheral portion of the region 440 of the surface 401. When the lid 40 is set in the jig 60 in this manner, the thin film 450 is not formed in the region of the surface 401 of the lid 40 held by the jig 60, and the thin film 450 is formed in the region which is not held by the jig 60 because the jig 60 has the opening.

However, in the region of the lid 40 held by the jig 60, a small scratch or crack can be generated in the surface 401 of the lid 40 due to contact between the lid 40 and the jig 60. Particularly, if a small scratch or crack exists in the outer peripheral portion of the region 440 of the lid 40, that is, on the inner side of the region 420 where the lid 40 is to be fixed to the base body 30, after the lid 40 is fixed to the base body 30, the lid 40 can break due to a stress caused by external environmental influence. More specifically, if the air in the internal space 50 expands due to high temperature, high temperature and humidity, high place, or the like, a high tensile stress is applied to the surface 401 of the lid 40 from the outer peripheral portion of the region 440 to the inner peripheral portion of the region 420, that is, the vicinity of the fixing portion between the base body 30 and the lid 40. Further, for example, due to the difference in linear expansion coefficient between the base body 30 using alumina ceramic, a resin, or the like and the lid 40 using quartz or the like, a high tensile stress is applied to the lid 40 in the vicinity of the fixing portion between the base body 30 and the lid 40. The tensile stress generated in the lid 40 causes the scratch or crack to extend, and the lid 40 can break.

If the shape of each of the base body 30 and the lid 40 in the plane direction is a square, the tensile stress on the lid 40 applied to the vicinity of the fixing portion between the base body 30 and the lid 40 is highest near the center of each side of the square. If the shape of the lid 40 in the plane direction is a rectangle, the tensile stress is highest near the center of a long side of the rectangle. Further, the tensile stress on the lid 40 has a distribution in which the stress gradually decreases, with the vicinity of the fixing portion between the base body 30 and the lid 40 as the center, from the side of the region 440 located on the inner side of the fixing portion of the lid 40 toward the side of the fixed region 420, and from the center of the side toward the outer side of the side. Due to the joint member such as the adhesive fixing the base body 30 and the lid 40, the tensile stress generated on the region 420 side of the lid 40 can be lower than the tensile stress on the region 440 side. For example, in the electronic component 100 including the lid 40 having a thickness of 0.5 mm or less, such as 0.1 mm, 0.2 mm, or 0.3 mm, and the size of 40 mm or more in each of the X and Y directions, it has become necessary to sufficiently consider the risk of breakage of the lid 40 as described above. The thickness of the lid 40 can be 0.03 mm, 0.05 mm, or the like.

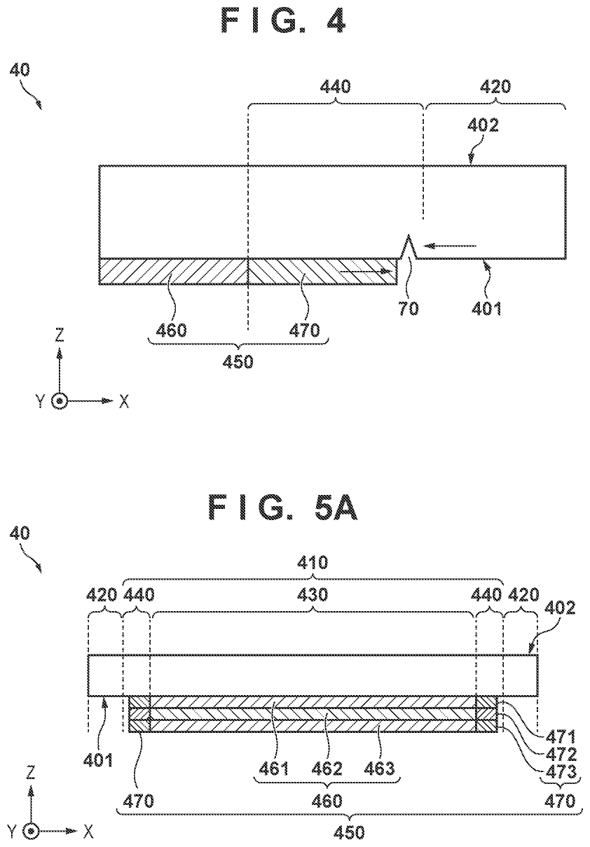

In order to suppress breakage of the lid 40, in this embodiment, the internal stress of the portion 470 of the thin film 450 arranged in the region 440 of the lid 40 is a tensile stress. That is, the portion 470 of the thin film 450 applies, to the portion of the lid 40 in contact with the portion 470 of the thin film 450, a force in a direction from the center of the thin film 450 toward the outer edge. FIG. 4 is an enlarged view showing the vicinity of the regions 420 and 440 of the lid 40. FIG. 4 shows the lid 40, a scratch 70 formed in the lid 40, and an image of the stress applied to each of the lid 40 and the portion 470 of the thin film 450. As has been described above, due to contact with the jig 60, the scratch 70 can be generated in the surface 401 of the lid 40 near the boundary between the region 420 and the region where the thin film 450 has been formed. In FIG. 4, an outward arrow in the portion 470 indicates that the internal stress of the portion 470 of the thin film 450 is a tensile stress. In this case, a compressive stress is applied to the lid 40 as a reaction force, and this is indicated by an inward arrow in the lid 40. In this manner, when the internal stress of the portion 470 of the thin film 450 is a tensile stress, a reaction force in the compression direction acts on the lid 40, so that the tensile stress of the lid 40 applied to the vicinity of the fixing portion between the base body 30 and the lid 40 is relaxed. This suppresses extension of the scratch or crack (for example, the scratch 70) formed in the surface 401 of the lid 40, resulting in suppressing damage of the lid 40 such as breakage of the lid 40.

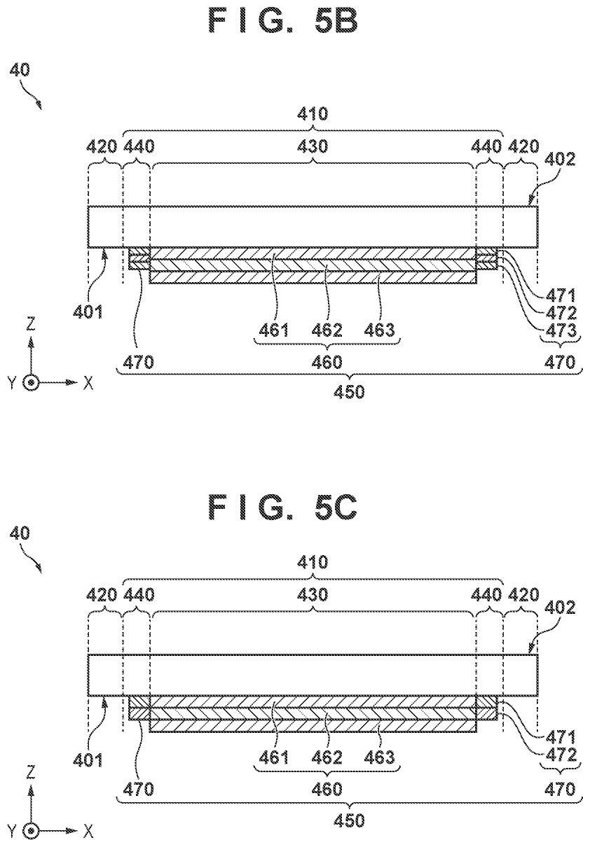

FIGS. 5A to 5C are views each showing an example of the arrangement of the thin film 450 arranged on the lid 40. Similar to FIG. 2, each of FIGS. 5A to 5C shows a section of the lid 40 taken along the line A-a in the plan view. The thin film 450 shown in each of FIGS. 5A to 5C is formed by including at least two kinds of material layers using materials different from each other. The portion 460 of the thin film 450 may include at least two kinds of material layers using materials different from each other. The portion 470 of the thin film 450 may include at least one kind of material layer, or may include at least two kinds of material layers using materials different from each other.

In the arrangement shown in FIG. 5A, three material layers 461, 462, and 463 are arranged in the portion 460 of the thin film 450, and three material layers 471, 472, and 473 are arranged in the portion 470. The materials layers 461, 462, and 463 may be three kinds of material layers, or, for example, the material layer 461 and the material layer 463 may be material layers of the same kind. Similarly, the material layers 471, 472, and 473 may be three kinds of material layers, or, for example, the material layer 471 and the material layer 473 may be material layers of the same kind. The layer arrangement shown in FIG. 5B is similar to the layer arrangement shown in FIG. 5A, but the thickness of the portion 470 of the thin film 450 is smaller than the thickness of the portion 470 shown in FIG. 5A. As a result, the film thickness of the portion 470 of the thin film 450 is smaller than the film thickness of the portion 460. In the arrangement shown in FIG. 5C, three material layers 461, 462, and 463 are arranged in the portion 460 of the thin film 450, and two material layers 471 and 472 are arranged in the portion 470. In the arrangement shown in FIG. 5C, the film thickness of the portion 470 of the thin film 450 is smaller than the film thickness of the portion 460, as in FIG. 5B. However, the present invention is not limited to this. By making the film thicknesses of the material layers 461 and 462 larger than the film thicknesses of the material layers 471, 472, and 473, for example, the portion 460 and the portion 470 of the thin film 450 may have the same film thickness, or the film thickness of the portion 460 of the thin film 450 may be smaller than the film thickness of the portion 470.

The portion 470 of the thin film 450 only needs to be formed such that its internal stress becomes a tensile stress. Therefore, the spectral characteristics of the portion 470 for antireflection, infrared cutting, or the like need not be similar to those of the portion 460 of the thin film 450 including the region which overlaps the electronic device 10. Accordingly, the material layers 471, 472, and 473 arranged in the portion 470 of the thin film 450 may have the minimum required structure, and the portion 470 may include the lesser material layers than the portion 460. With this, steps for forming the thin film 450 can be reduced.

In the arrangement shown in each of FIGS. 5A to 5C, two or three material layers 461, 462, and 463 are arranged as the portion 460 of the thin film 450, and two or three material layers 471, 472, and 473 are arranged as the portion 470 of the thin film 450. However, the present invention is not limited to this. Four or more material layers may be arranged, or even ten or more material layers may be arranged. For example, in the portion 470 of the thin film 450, a single material layer may be arranged. An optimal arrangement can be employed in accordance with the required characteristics.

For example, as the material layers 471, 472, and 473 forming the portion 470 of the thin film 450, SiO₂, TiO₂, or the like may be used. On the other hand, as the material layers 461, 462, and 463 forming the portion 460 of the thin film 450, MgF₂, Nb₂O₅, ZrO₂, or the like may be used. In this manner, the material used for the portion 460 of the thin film 450 may be different from the material used for the portion 470. For the portion 460, the material layer according to the optical characteristics required for the electronic component 100 is used. In this case, the portion 460 of the thin film 450 may apply, to the portion of the lid 40 in contact with the portion 460, a force in a direction from the center of the thin film 450 toward the outer edge (the internal stress of the portion 460 of the thin film 450 is a tensile stress), or a force in a direction from the outer edge of the thin film 450 toward the center (the internal stress of the portion 460 of the thin film 450 is a compressive stress). As has been described above, a material layer in which the internal stress becomes a tensile stress is used for the portion 470.

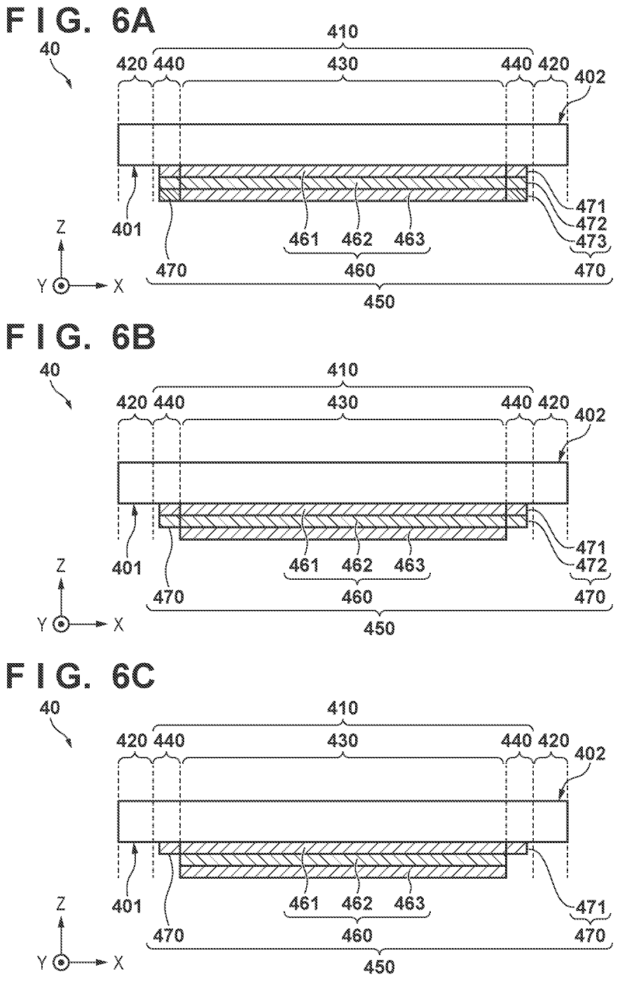

FIGS. 6A to 6C are views each showing an example of the arrangement of the thin film 450 arranged on the lid 40, which is different from the examples shown in FIGS. 5A to 5C. Similar to FIG. 2, each of FIGS. 6A to 6C shows a section of the lid 40 taken along the line A-a in the plan view. In the arrangement shown in FIG. 6A, three material layers 461, 462, and 463 are arranged in the portion 460 of the thin film 450, and three material layers 471, 472, and 473 are arranged in the portion 470. In this case, for example, the material layer 471 and the material layer 461 may be material layers using the same material, and the material layer 472 and the material layer 462 may be material layers using the same material. That is, in the arrangement shown in FIG. 6A, two of three material layers 461, 462, and 463 arranged in the portion 460 and two of three material layers 471, 472, and 473 arranged in the portion 470 may be material layers using the same material, respectively, and the material layer 463 and the material layer 473 may be material layers using materials different from each other.

The arrangement shown in FIG. 6B is different from the arrangement shown in FIG. 6A in that the material layer 473 is not formed and two-layered arrangement is formed. The arrangement shown in FIG. 6C is different from the arrangement shown in FIG. 6A in that the material layers 472 and 473 are not formed so that the portion 470 has a single layer structure. The arrangement shown in each of FIGS. 6A to 6C is also formed such that the internal stress of the portion 470 of the thin film 450 becomes a tensile stress. In this case, the number of steps for forming the thin film 450 can be reduced as compared to a case in which all the material layers 471, 472, and 473 forming the portion 470 are different from the material layers 461, 462, and 463 forming the portion 460. For example, when TiO₂ is used as the material layers 461, 462, and 463 forming the portion 460 of the thin film 450, TiO₂ may be used as the material layers 461, 462, and 463 forming the portion 470. In this manner, the material used for the material layer of the portion 470 of the thin film 450 may be the same as the material used for one of the material layers of the portion 460. Each of FIGS. 6A to 6C also shows the case in which three or less material layers are arranged in each of the portions 460 and 470 of the thin film 450. However, four or more layers may be arranged, and a combination of the number of layers of the portion 460 and that of the portion 470 can be optimally configured in accordance with the required characteristics.

For the thin film 450 shown in each of FIGS. 5A to 5C, for example, the portion 460 of the thin film 450 is formed using the jig 60 as shown in FIG. 3. Then, the portion 460 may be masked, and the portion 470 of the thin film 450 may be formed using another jig that includes an opening corresponding to a region where the portion 470 is to be formed. For the thin film 450 shown in each of FIGS. 6A to 6C, for example, the first one or some layers of the thin film 450 are formed using the jig 60 as shown FIG. 3 that includes an opening corresponding to a region of the thin film 450 where the portion 460 and the portion 470 are to be formed. After that, the area from the intermediate layer to the portion 470 may be masked, and the thin film 450 may be formed using a jig that includes an opening corresponding only to the region where the portion 460 is to be formed.

As has been described above, the thin film 450 is arranged on the lid 40 so that the internal stress of the portion 470 of the thin film 450 becomes a tensile stress. With this, extension of a small scratch, crack, or the like existing in the surface 401 of the lid 40 is suppressed, and the electronic component 100 with suppressed damage of the lid 40 can be provided.

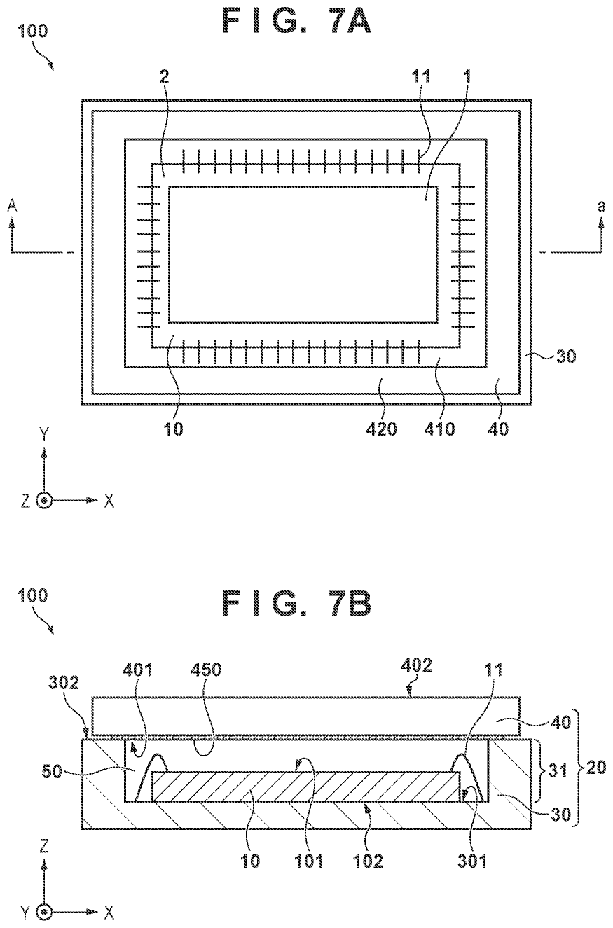

FIGS. 7A and 7B are views showing a modification of the electronic component 100 shown in FIGS. 1A and 1B. In the arrangement shown in FIGS. 7A and 7B, the thin film 450 arranged on the surface 401 of the lid 40 is formed not only in the region 410 of the lid but also in a portion of the region 420 in contact with the region 410. The remaining arrangement may be similar to that of the electronic component 100 described above, so that different points will be mainly described below.

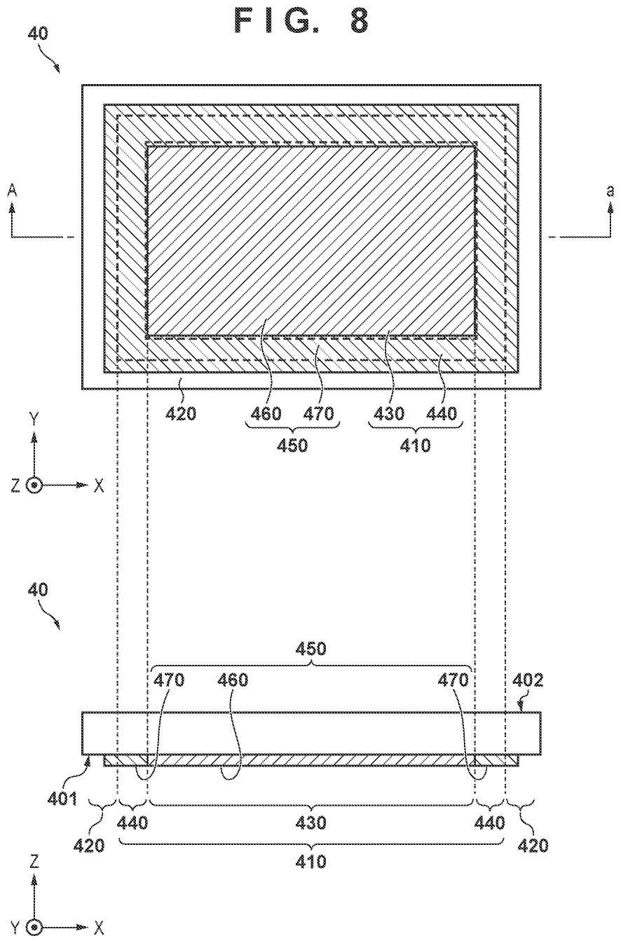

FIG. 8 is a schematic view showing an example of the arrangement of the lid 40 of the electronic component 100 shown in FIGS. 7A and 7B. A plan view of the lid 40 is shown on the upper side of FIG. 8, and a sectional view of the lid 40 is shown on the lower side. The sectional view shows a section of the lid 40 taken along the line A-a in the plan view. With reference to FIG. 8, the lid 40 of the electronic component 100 shown in FIGS. 7A and 7B will be described in more detail. As shown in FIGS. 7A, 7B, and 8, in the orthogonal projection with respect to the placement surface 301, the outer edge of the thin film 450 is arranged so as to overlap the frame portion 31 of the base body 30. That is, the thin film 450 is also formed in the outer peripheral portion of the region 440 and the inner peripheral portion of the region 420 of the lid 40 where the thin film 450 is not formed in the arrangements shown in FIGS. 1A to 6 described above. Also in this embodiment, the internal stress of the portion 470 including the outer edge of the thin film 450 is a tensile stress.

It has been described above that, if the adhesive used as the joint member for fixing the base body 30 and the lid 40 is an ultraviolet curing adhesive, the thin film 450 can be a factor that hinders curing of the adhesive. However, when forming the thin film 450, in the region of the surface 401 of the lid 40 where the thin film 450 is not formed, a small scratch or crack can be generated due to contact between the lid 40 and the jig 60. Hence, as shown in FIGS. 7A, 7B, and 8, by forming the thin film 450 (portion 470) up to the inner peripheral portion of the region 420 of the lid 40, the region where the scratch and crack are likely to be generated can be limited to the outer peripheral portion of the region 420. In FIGS. 7A, 7B, and 8, the thin film 450 (portion 470) may be formed in half or more of the region 420 between the outer edge of the lid 40 and the boundary with the region 440 in the orthogonal projection with respect to the placement surface 301. That is, in the orthogonal projection with respect to the placement surface 301, the outer edge of the thin film 450 (portion 470) may be arranged at a position closer to the outer edge of the lid 40 than a virtual line that bisects the region 420, where the lid 40 overlaps the frame portion 31, between the outer edge of the lid 40 and the inner edge of the frame portion 31 (to be also referred to as the outer edge of the region 410 of the lid 40, or the inner edge of the region 420 of the lid 40). If the air in the internal space 50 expands due to high temperature, high temperature and humidity, high place, or the like, the tensile stress applied to the vicinity of the fixing portion between the base body 30 and the lid 40 is lower on the region 420 side than on the region 440 side, as has been described above. However, even in the region 420, the tensile stress applied to the vicinity of the fixing portion between the base body 30 and the lid 40 can be high enough to influence damage of the lid 40 depending on the thickness and size of the lid 40.

Therefore, as shown in FIGS. 7A, 7B, and 8, the portion 470 of the thin film 450 is formed up to the inner peripheral portion of the region 420. Further, by fixing the scratch or the like with a joint member such as an adhesive, the tensile stress applied to the region 420 of the lid 40 is relaxed. Thus, extension of the scratch or crack is suppressed, and damage of the lid 40 such as breakage can be suppressed. If the adhesive used as the joint member for fixing the lid 40 to the base body 30 is an ultraviolet curing adhesive, as a countermeasure against inhibition of curing due to the influence of the thin film 450, an appropriate countermeasure may be taken, such as extending the irradiation time of ultraviolet light for curing the adhesive. Alternatively, for example, a thermosetting adhesive may be used as the joint member for joining the base body 30 and the lid 40. In this case, it is necessary to sufficiently consider the stress applied to the lid 40 due to a temperature rise during thermosetting.

Also in the arrangement shown in FIGS. 7A, 7B, and 8, it is possible to employ a combination of material layers for each of the portions 460 and 470 of the thin film 450 as shown in each of FIGS. 5A to 5C and FIGS. 6A to 6C. Further, for example, if the shape of the lid 40 in the X-Y direction is rectangular, the thin film 450 (portion 470) may be arranged only in the region 420 on the long side, and the thin film 450 (portion 470) may not be arranged in the region 420 on the short side. When the thin film 450 (portion 470) is formed only in the required region, the cost of forming the thin film 450 (portion 470) and the number of steps for joining the base body 30 and the lid 40 can be suppressed.

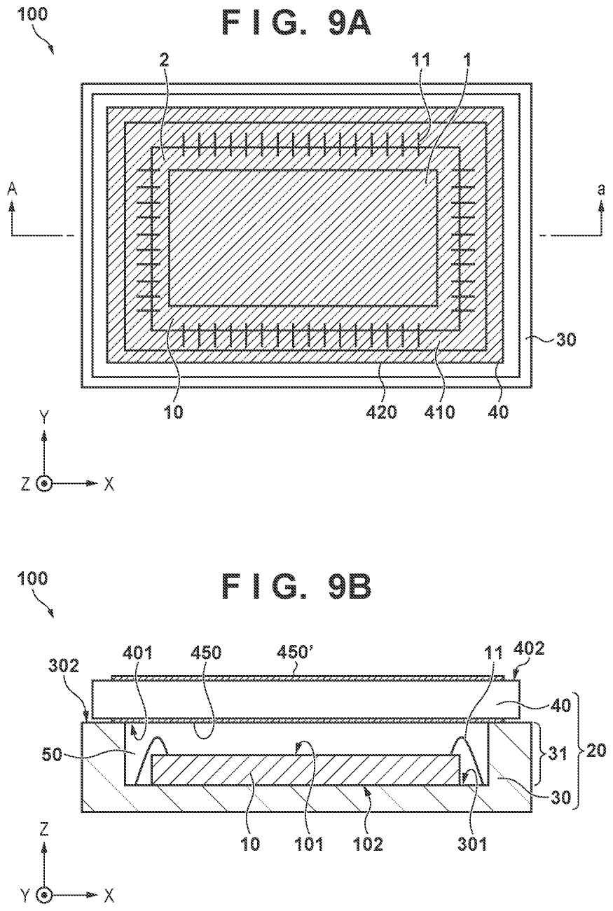

FIGS. 9A and 9B are views showing a modification of the electronic component 100 shown in FIGS. 7A and 7B. In the arrangement shown in FIGS. 9A and 9B, in addition to the thin film 450 arranged on the surface 401 of the lid 40, a thin film 450′ in contact with the surface 402 is arranged on the surface 402 on the opposite side of the surface 401 of the lid 40. When the thin films 450 and 450′ are formed on both the surfaces 401 and 402 of the lid 40, respectively, the antireflection performance, infrared cutting performance, and the like can be further improved. The remaining arrangement may be similar to that of the electronic component 100 described above, so that different points will be mainly described below.

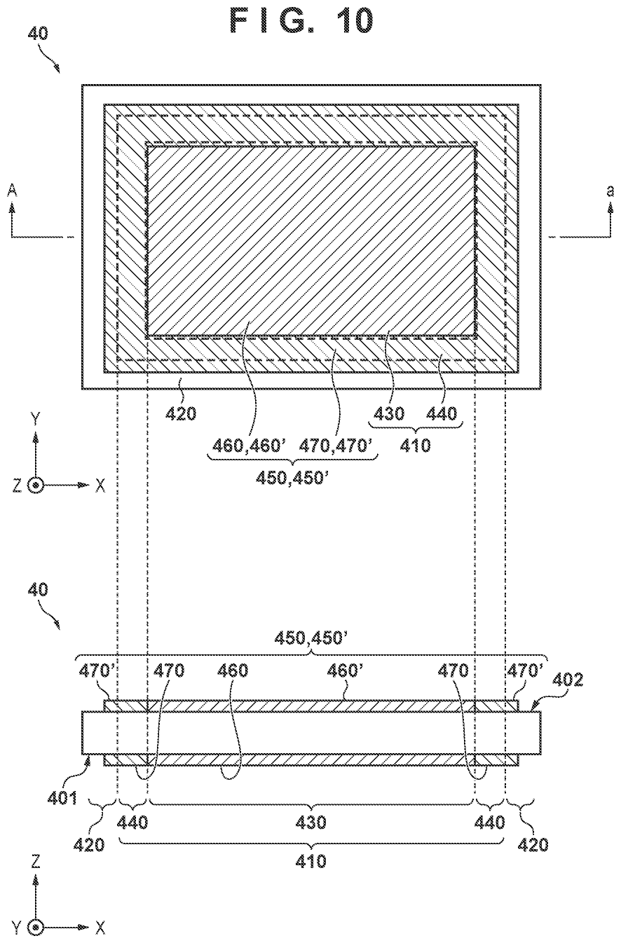

FIG. 10 is a schematic view showing an example of the arrangement of the lid 40 of the electronic component 100 shown in FIGS. 9A and 9B. A plan view of the lid 40 is shown on the upper side of FIG. 10, and a sectional view of the lid 40 is shown on the lower side. The sectional view shows a section of the lid 40 taken along the line A-a in the plan view. With reference to FIG. 10, the lid 40 of the electronic component 100 shown in FIGS. 9A and 9B will be described in more detail.

In the orthogonal projection with respect to the placement surface 301, the thin film 450′ includes a portion 460′ including a region which overlaps the electronic device 10, and a portion 470′ arranged so as to surround the portion 460′ and including the outer edge of the thin film 450′. It can also be said that the thin film 450′ is formed by the portion 460′ and the portion 470′. The portion 460′ of the thin film 450′ including the region which overlaps the electronic device 10 needs to have specifications that implement the antireflection performance, infrared cutting performance, and the like required for the electronic component 100. On the other hand, also in this embodiment, the internal stress of the portion 470′ of the thin film 450′ arranged in the region 440 of the lid 40 is a tensile stress. That is, the portion 470′ of the thin film 450′ applies, to the portion of the lid 40 in contact with the portion 470′ of the thin film 450′, a force in a direction from the center of the thin film 450′ toward the outer edge.

In the arrangement shown in FIG. 10, the portion 460′ of the thin film 450′ is arranged so as to overlap the region 430 of the lid 40, and the portion 470′ of the thin film 450′ is arranged so as to overlap the region 440 of the lid 40. However, the present invention is not limited to this, and the portion 460′ of the thin film 450′ may be arranged so as to overlap the region 440 of the lid 40. Alternatively, for example, the portion 470′ of the thin film 450′ may be arranged so as to overlap the region 430 of the lid 40 to the extent not to impair the specifications required for the electronic component 100 such as antireflection and infrared cutting performances.

As shown in FIGS. 9A, 9B, and 10, similar to the arrangement shown in FIGS. 7A, 7B, and 8, the portion 470′ forming the outer edge of the thin film 450′ may be arranged in the region 420 of the lid 40. That is, in the orthogonal projection with respect to the placement surface 301, the outer edge of the thin film 450′ may be arranged so as to overlap the frame portion 31 of the base body 30. Alternatively, similar to the arrangement shown in FIGS. 1A, 1B, and 2, in the orthogonal projection with respect to the placement surface 301, the outer edge of the thin film 450′ may be arranged on the inner side of the frame portion 31 of the base body 30.

In the arrangement shown in FIGS. 9A, 9B, and 10, the thin film 450 formed on the surface 401 of the lid 40 may have an arrangement similar to the arrangement shown in FIGS. 7A, 7B, and 8. Further, the thin film 450′ arranged on the surface 402 of the lid 40 may have, for example, an arrangement similar to the arrangement of the thin film 450, and the thin film 450 and the thin film 450′ may be arranged so as to overlap each other in the orthogonal projection with respect to the placement surface 301.

Also in the thin film 450′ arranged on the surface 402 of the lid 40, the internal stress of the portion 470′ is a tensile stress. When forming the thin film 450′ on the surface 402, a small scratch or crack can be generated in the surface 402 due to contact between the lid 40 and the jig 60. In high temperature, high temperature and humidity, high place, or the like, the tensile stress on the surface 402 side applied to the vicinity of the fixing portion between the base body 30 and the lid 40 can be lower than the tensile stress applied on the surface 401 side. However, in low temperature or the like, a high stress can be applied to the vicinity of the fixing portion between the base body 30 and the lid 40 on the surface 402 side. Therefore, by arranging, on the surface 402, the thin film 450′ (portion 470′) which applies a tensile stress as the internal stress, extension of the scratch or crack in the surface 402 of the lid 40 in low temperature or the like is suppressed, and damage of the lid 40 can be suppressed.

Similar to the thin film 450, for the thin film 450′, it is possible to employ a combination of material layers for each of the portions 460′ and 470′ of the thin film 450′ as shown in each of FIGS. 5A to 5C and FIGS. 6A to 6C described above. In consideration of the stress applied to the lid 40 and the risk of damage of the lid 40, the thin film 450′ is formed only in the required region. With this, the cost and number of steps for forming the thin film 450′ (portion 470′) can be suppressed.

The thin film 450′ may have the same arrangement as the thin film 450, or may have different arrangement. The arrangement of the material layers and the like may be selected, as appropriate, in accordance with the optical characteristics and internal stress required for each of the thin film 450 and the thin film 450′.

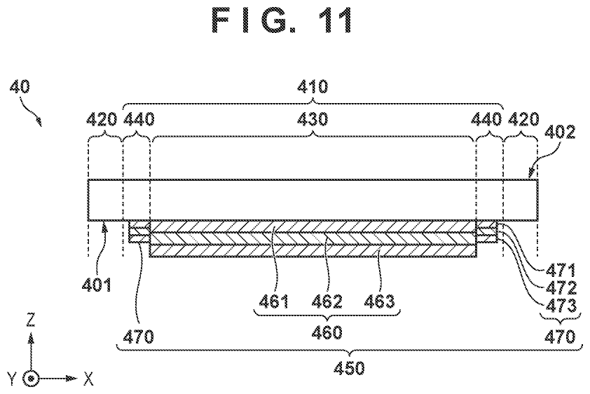

FIG. 11 is a sectional view showing an example of the arrangement of the lid 40 of the electronic component 100 different from the arrangement described above. In the arrangement shown in FIG. 11, the arrangement of the thin film 450 arranged on the surface 401 of the lid 40 is different from the arrangement described above. The remaining points may be similar to those of the electronic component 100 described above, so that different points will be mainly described below.

In the orthogonal projection with respect to the placement surface 301, the thin film 450 includes the portion 460 including a region which overlaps the electronic device 10, and the portion 470 arranged so as to surround the portion 460 and including the outer edge of the thin film 450. Each of the portions 460 and 470 includes at least two kinds of material layers using materials different from each other. In the arrangement shown in FIG. 11, similar to the arrangement shown in FIG. 6A, three material layers 461, 462, and 463 are arranged in the portion 460 of the thin film 450, and three material layers 471, 472, and 473 are arranged in the portion 470. Further, similar to the arrangement shown in FIG. 6A, the material layer 471 and the material layer 461 are material layers using the same material, and the material layer 472 and the material layer 462 are material layers using the same material. Furthermore, in the arrangement shown in FIG. 11, unlike the arrangement shown in FIG. 6A, the material layer 473 and the material layer 463 are material layers using the same material. That is, the stacking order of at least two kinds of material layers in the portion 460 is the same as the stacking order of at least two kinds of material layers in the portion 470.

Here, as shown in FIG. 11, the material layer 471 is thinner than the material layer 461, the material layer 472 is thinner than the material layer 462, and the material layer 473 is thinner than the material layer 463. It can also be said that the film thickness of a given kind of material layer of at least two kinds of material layers of the portion 470 is smaller than the film thickness of the same kind of the material layer in the portion 460. In this embodiment, in the thin film 450, the material layers 461, 462, and 463, and the material layers 471, 472, and 473 are sequentially formed while using the same materials for the portion 460 and the portion 470. On the other hand, the material layers 471, 472, and 473 arranged in the portion 470 are thinner than the corresponding material layers 461, 462, and 463 arranged in the portion 460. Therefore, the film thickness of the portion 470 of the thin film 450 is smaller than the film thickness of the portion 460.

Alternatively, for example, the material layers 471, 472, and 473 arranged in the portion 470 may be lower in density than the corresponding material layers 461, 462, and 463 arranged in the portion 460. It can also be said that the density of a given kind of material layer of at least two kinds of material layers in the portion 470 is lower than the density of the same kind of material layer in the portion 460.

In general, stable and highly reliable performances such as antireflection and infrared cutting performance are required for the portion 460 of the thin film 450, so that it is necessary to form a fine and high-density thin film with a stable deposition thickness and high adhesion to the lid 40. When the material of the thin film and the formation conditions for the thin film are selected to form the portion 460 of the thin film 450 as described above, the internal stress of the formed thin film often becomes a very high compressive stress. For example, in a case in which SiO₂ or the like is used for the low refractive index material, or in a case in which TiO₂ or the like is used for the high refractive index material, depending on the formation conditions of the thin film 450 (portion 460), the internal stress of the portion 460 tends to be a high compressive stress. Therefore, as the portion 460 of the thin film 450 arranged in the region 430 to overlap the electronic device 10, which requires a fine thin film with a stable deposition thickness and high adhesion, the portion 460 whose internal stress becomes a high compressive stress is formed, and the portion 470 thinner and lower in density than the portion 460 is formed in the region 440 that does not require the fine thin film with the stable deposition thickness and high adhesion. With this, the portion 470 of the thin film 450 can have a lower compressive stress than the portion 460.

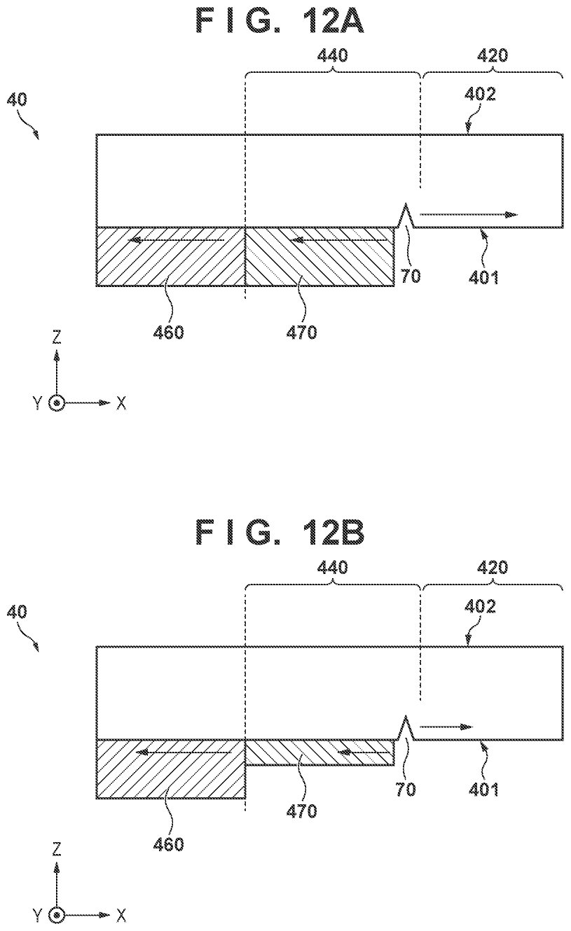

Each of FIGS. 12A and 12B is an enlarged view showing the vicinity of the regions 420 and 440 of the lid 40. Each of FIGS. 12A and 12B shows the lid 40, the scratch 70 formed in the lid 40, and an image of the stress applied to each of the lid 40 and the portions 460 and 470 of the thin film 450.

FIG. 12A shows a case in which the portions 460 and 470 of the thin film 450 have the same arrangement. The internal stress of the thin film 450 (portions 460 and 470) is a compressive stress, and the thin film 450 (portions 460 and 470) applies, to the portion of the lid 40 in contact with the thin film 450 (portions 460 and 470), a force in the direction from the outer edge of the thin film 450 toward the center of the thin film 450. On the other hand, FIG. 12B shows a case in which the internal stress of the portion 460 of the thin film 450 is a high compressive stress, and the portion 470 is thinner than the portion 460 so that the compressive stress thereof is lower than that of the portion 460. It can also be said that the portion 460 of the thin film 450 applies, to the portion of the lid 40 in contact with the portion 460, a force in the direction from the outer edge of the thin film 450 toward the center of the thin film 450, and the portion 470 applies, to the portion of the lid 40 in contact with the portion 470, a force in the direction from the outer edge of the thin film 450 toward the center of the thin film 450, which is lower than the force of the portion 460. In FIGS. 12A and 12B, inward arrows in the portions 460 and 470 indicate that the internal stresses of the portions 460 and 470 of the thin film 450 are compressive stresses, respectively, and the length of the arrow indicates the magnitude of the stress. In this case, a tensile stress is applied to the lid 40 as a reaction force, and this is indicated by an outward arrow in the lid 40.

In the arrangement shown in FIG. 12A, a high tensile stress is applied to the lid 40. On the other hand, in the arrangement shown in FIG. 12B, both the internal stress of the portion 460 and the internal stress of the portion 470 of the thin film 450 are compressive stresses, but the stress of the portion 470 is lower than the stress of the portion 460. Therefore, the tensile stress applied to the lid 40 is also low. That is, the arrangement shown in FIG. 12B is formed. With this arrangement, the internal stress of the portion 470 of the thin film 450 has a smaller effect of suppressing damage of the lid 40 than in the case in which the internal stress is a tensile stress as shown in FIG. 4, but can suppress damage of the lid 40 as compared to the case in which the entire thin film 450 applies a high compressive stress. That is, damage of the lid 40 such as breakage can be suppressed.

As shown in FIGS. 9A, 9B, and 10, the thin film 450 including the portion 470 where the internal stress is a compressive stress may be formed not only on the surface 401 of the lid 40 but also on the surface 402 (thin film 450′). In that case, the thin film 450 and the thin film 450′ may have the same arrangement or arrangements different from each other. For example, the thin film 450 arranged on the surface 401 of the lid 40 may include the portion 470 where the internal stress is a tensile stress, and the thin film 450′ arranged on the surface 402 of the lid 40 may include the portion 470′ where the internal stress is a compressive stress. Further, for example, the outer edge of the thin film 450 may be arranged so as to overlap the region 420 of the lid 40. The various combinations described above are also applicable in a case in which the internal stress of the portion 470 of the thin film 450 is a compressive stress.

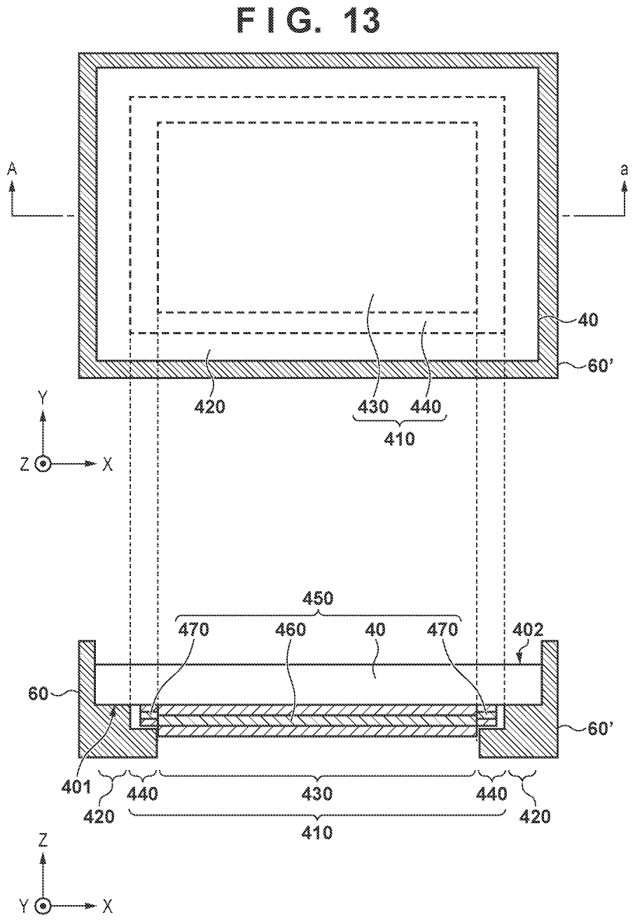

As a method of forming the thin film 450 as shown in FIGS. 11 and 12B, for example, a jig 60′ as shown in FIG. 13 can be used. Similar to FIG. 3, FIG. 13 is a schematic view showing the relationship between the lid 40 and the jig 60′ upon forming the thin film 450 on the lid 40. A plan view in a state in which the lid 40 is set in the jig 60′ is shown on the upper side of FIG. 13, and a sectional view is shown on the lower side. The sectional view shows a section taken along the line A-a in the plan view.

The jig 60′ holds the outer shape of the lid 40 in the X-Y direction and the region 420 of the lid 40 on the surface 401 side. Further, the jig 60′ has a shape such that a space is arranged between the lid 40 and the jig 60′ in the region which overlaps the region 440 in the orthogonal projection with respect to the surface 401 of the lid 40. By setting the lid 40 in the jig 60′ having the shape as described above, when forming the thin film 450, the thin film 450 is not formed in the region (for example, the region 420) of the lid 40 held by the jig 60′. In the region 430 of the lid 40 which is not held by the jig 60′ because the jig 60′ has an opening, the portion 460 of the thin film 450 is formed. Further, the jig 60′ exists on the region 440 of the lid 40, but the space exists between the lid 40 and the jig 60′. Hence, the portion 470 of the thin film 450 is formed by part of the thin film material of the thin film 450 obliquely entering the space. Thus, the portion 470 having a smaller film thickness than the portion 460 of the thin film 450 is formed. Further, the portion 470 having a lower density than the portion 460 of the thin film 450 is formed.

Depending on the size of the space on the region 440 of the lid 40 between the lid 40 and the jig 60′, the film thickness and density of the portion 470 of the thin film 450 to be formed change. It has been described above that the portion 470 of the thin film 450 has the smaller film thickness and lower density than the portion 460. However, for example, the portion 460 and the portion 470 of the thin film 450 may have different film thicknesses but the same density. Alternatively, for example, the portion 460 and the portion 470 of the thin film 450 may have different densities but the same film thickness. The size of the space on the region 440 of the lid 40 between the lid 40 and the jig 60′ can be designed, as appropriate, in consideration of the stress of the portion 470 of the thin film 450 and the like. In the arrangement shown in FIGS. 11 to 13, the portion 460 and the portion 470 of the thin film 450 can be collectively formed. Accordingly, the thin film 450 can be more easily formed than in the case in which the portion 460 and the portion 470 of the thin film 450 have different arrangements as described above, so that the material cost and the number of steps for forming the thin film 450 can be reduced.

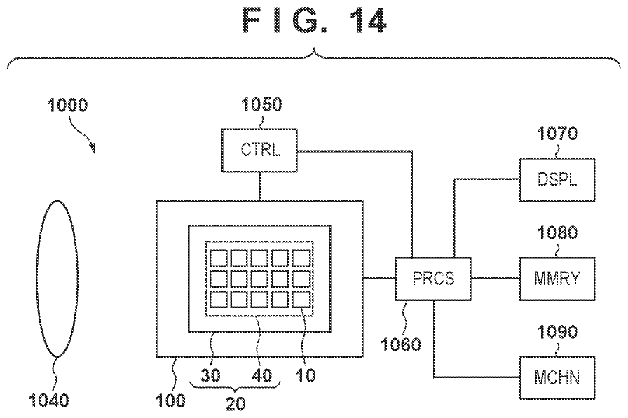

Equipment 1000 including the electronic component 100 shown in FIG. 14 will be described below in detail. The electronic device 10 is accommodated in the package 20 and mounted in the equipment 1000. In the arrangement shown in FIG. 14, the electronic device 10 is a photoelectric conversion device. The electronic component 100 can include the package 20 that includes the base body 30 with the electronic device 10 fixed thereon and the lid 40 made of glass or the like facing the electronic device 10. As has been described above, the joint members such as the wire 11 and bumps for connecting an internal terminal of the base body 30 and a terminal such as a pad electrode of the electronic device 10 can be arranged in the package 20.

The equipment 1000 can include at least one of an optical apparatus 1040, a control apparatus 1050, a processing apparatus 1060, a display apparatus 1070, a storage apparatus 1080, and a mechanical apparatus 1090. The optical apparatus 1040 is implemented by, for example, a lens, a shutter, and a mirror. The control apparatus 1050 controls the electronic device 10. The control apparatus 1050 is, for example, a semiconductor apparatus such as an ASIC.

The processing apparatus 1060 processes a signal output from the electronic device 10. The processing apparatus 1060 is a semiconductor apparatus such as a CPU or an ASIC for forming an Analog Front End (AFE) or a Digital Front End (DFE). The display apparatus 1070 is an EL display apparatus or a liquid crystal display apparatus that displays information (image) obtained by the electronic device 10. The storage apparatus 1080 is a magnetic device or a semiconductor device that stores the information (image) obtained by the electronic device 10. The storage apparatus 1080 is a volatile memory such as an SRAM or a DRAM, or a nonvolatile memory such as a flash memory or a hard disk drive.

The mechanical apparatus 1090 includes a moving or propulsion unit such as a motor or an engine. In the equipment 1000, the signal output from the electronic device 10 is displayed on the display apparatus 1070 or transmitted to an external apparatus by a communication apparatus (not shown) included in the equipment 1000. Hence, the equipment 1000 may further include the storage apparatus 1080 and the processing apparatus 1060 in addition to the memory circuits and arithmetic circuits included in the electronic device 10. The mechanical apparatus 1090 may be controlled based on the signal output from the electronic device 10.

In addition, the equipment 1000 is suitable for electronic equipment such as an information terminal (for example, a smartphone or a wearable terminal) which has a shooting function or a camera (for example, an interchangeable lens camera, a compact camera, a video camera, or a monitoring camera). The mechanical apparatus 1090 in the camera can drive the components of the optical apparatus 1040 in order to perform zooming, an in-focus operation, and a shutter operation. Alternatively, the mechanical apparatus 1090 in the camera can move the electronic device 10 in order to perform an anti-vibration operation.

Furthermore, the equipment 1000 can be transportation equipment such as a vehicle, a ship, or an airplane. The mechanical apparatus 1090 in the transportation equipment can be used as a moving apparatus. The equipment 1000 as the transportation equipment is suitable for an apparatus that transports the electronic device 10 or an apparatus that uses a shooting function to assist and/or automate driving (steering). The processing apparatus 1060 for assisting and/or automating driving (steering) can perform, based on the information obtained by the electronic device 10, processing for operating the mechanical apparatus 1090 as a moving apparatus. Alternatively, the equipment 1000 may be medical equipment such as an endoscope, measurement equipment such as a distance measurement sensor, analysis equipment such as an electron microscope, office equipment such as a copy machine, or industrial equipment such as a robot.

According to the present invention, a technique advantageous in suppressing damage of the lid can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-065900, filed Apr. 13, 2023, which is hereby incorporated by reference herein in its entirety.

What is claimed is:

1. An electronic component that comprises a base body with an electronic device placed on a placement surface, and a lid including a surface facing the electronic device and fixed to the base body, wherein
on the surface of the lid, a thin film in contact with the surface is arranged,
in an orthogonal projection with respect to the placement surface, the thin film comprises a first portion including a region which overlaps the electronic device, and a second portion arranged so as to surround the first portion and including an outer edge of the thin film, and
the second portion applies, to a portion of the lid in contact with the second portion, a force in a direction from a center of the thin film toward the outer edge.

2. The component according to claim 1, wherein
the first portion includes at least two kinds of material layers using materials different from each other.

3. The component according to claim 2, wherein
the second portion includes at least one kind of material layer, and
a number of layers of the second portion is smaller than a number of layers of the first portion.

4. The component according to claim 2, wherein
a material used for the first portion and a material used for the second portion are different from each other.

5. The component according to claim 2, wherein
the second portion includes at least one kind of material layer, and
a material used for the at least one kind of material layer of the second portion is the same as a material used for one of the at least two kinds of material layers of the first portion.

6. The component according to claim 1, wherein
the second portion includes at least two kinds of material layers using materials different from each other.

7. The component according to claim 1, wherein
the first portion applies, to a portion of the lid in contact with the first portion, a force in a direction from the outer edge toward the center.

8. The component according to claim 1, wherein
the surface of the lid is a first surface, and the thin film is a first thin film,
on a second surface on an opposite side of the first surface of the lid, a second thin film in contact with the second surface is arranged,
in the orthogonal projection with respect to the placement surface, the second thin film comprises a third portion including a region which overlaps the electronic device, and a fourth portion arranged so as to surround the third portion and including an outer edge of the second thin film, and
the fourth portion applies, to a portion of the lid in contact with the fourth portion, a force in a direction from a center of the second thin film toward the outer edge of the second thin film.

9. An electronic component that comprises a base body with an electronic device placed on a placement surface, and a lid including a surface facing the electronic device and fixed to the base body, wherein
on the surface of the lid, a thin film in contact with the surface is arranged,
in an orthogonal projection with respect to the placement surface, the thin film comprises a first portion including a region which overlaps the electronic device, and a second portion arranged so as to surround the first portion and including an outer edge of the thin film,
the first portion applies, to a portion of the lid in contact with the first portion, a force in a direction from the outer edge toward a center of the thin film, and
the second portion applies, to a portion of the lid in contact with the second portion, a force in the direction which is smaller than the force of the first portion.

10. The component according to claim 9, wherein
the first portion includes at least two kinds of material layers using materials different from each other, and
the second portion includes the at least two kinds of material layers.

11. The component according to claim 10, wherein
a stacking order of the at least two kinds of material layers in the first portion is the same as a stacking order of the at least two kinds of material layers in the second portion.

12. The component according to claim 10, wherein
a film thickness of a first kind of material layer of the at least two kinds of material layers in the second portion is smaller than a film thickness of the first kind of material layer in the first portion.

13. The component according to claim 12, wherein
a density of the first kind of material layer in the second portion is lower than a density of the first kinds of material layer in the first portion.

14. The component according to claim 10, wherein
a density of a first kind of material layer of the at least two kinds of material layers in the second portion is lower than a density of the first kind of material layer in the first portion.

15. The component according to claim 9, wherein
the surface of the lid is a first surface, and the thin film is a first thin film,
on a second surface on an opposite side of the first surface of the lid, a second thin film in contact with the second surface is arranged,
in the orthogonal projection with respect to the placement surface, the second thin film comprises a third portion including a region which overlaps the electronic device, and a fourth portion arranged so as to surround the third portion and including an outer edge of the second thin film,
the third portion applies, to a portion of the lid in contact with the third portion, a force in a second direction from the outer edge of the second thin film toward a center of the second thin film, and
the fourth portion applies, to a portion of the lid in contact with the fourth portion, a force in the second direction which is smaller than the force of the third portion.

16. The component according to claim 1, wherein
a film thickness of the second portion is smaller than a film thickness of the first portion.

17. The component according to claim 1, wherein
the base body includes a frame portion with the lid fixed thereon, and
in the orthogonal projection with respect to the placement surface, the outer edge is arranged on an inner side of the frame portion.

18. The component according to claim 1, wherein
the base body includes a frame portion with the lid fixed thereon, and
in the orthogonal projection with respect to the placement surface, the outer edge is arranged so as to overlap the frame portion.

19. The component according to claim 18, wherein
in the orthogonal projection with respect to the placement surface, the outer edge is arranged at a position closer to an outer edge of the lid than a virtual line that bisects a region, where the lid overlaps the frame portion, between the outer edge of the lid and an inner edge of the frame portion.

20. Equipment comprising:
an electronic component defined in claim 1; and
a processing apparatus configured to process a signal output from the electronic component.
